(19) United States
(12) Patent Application Publication
(10) Pub. No.: US 2026/0090260 A1
(43) Pub. Date: Mar. 26, 2026

(54) SEAMLESS DISPLAY DEVICE AND MANUFACTURING METHOD OF THE SAME

(71) Applicant: ELECTRONICS AND TELECOMMUNICATIONS RESEARCH INSTITUTE, Daejeon (KR)

(72) Inventors: Ji Hun CHOI, Daejeon (KR); Yongduck KIM, Daejeon (KR); Jong-Heon YANG, Daejeon (KR); Jiho JOO, Daejeon (KR); Jae-Eun PI, Daejeon (KR)

(73) Assignee: ELECTRONICS AND TELECOMMUNICATIONS RESEARCH INSTITUTE, Daejeon (KR)

(21) Appl. No.: 19/337,342

(22) Filed: Sep. 23, 2025

(30) Foreign Application Priority Data
Sep. 24, 2024 (KR) 10-2024-0129246
Sep. 4, 2025 (KR) 10-2025-0125411

(51) Int. Cl. H10K 77/10; H10K 59/12; H10K 59/131

(52) U.S. Cl. CPC H10K 77/111; H10K 59/1201; H10K 59/131

(57) ABSTRACT

Disclosed are a display device and a manufacturing method of the same. The manufacturing method of the display device includes providing a light shield pattern on a support substrate of a display region adjacent to a peripheral region, providing a flexible layer on the light shield pattern and the support substrate, providing a display element and a driver on the flexible layer of the display region and the peripheral region, respectively, providing laser light to the support substrate and the flexible layer of the peripheral region to separate a portion of the flexible layer from the support substrate, removing a portion of the support substrate of the peripheral region, and bending a portion of the flexible layer of the peripheral region to provide the driver on a bottom surface of the support substrate.

### CROSS-REFERENCE TO RELATED APPLICATIONS

This U.S. non-provisional patent application claims priority under 35 U.S. C. § 119 of Korean Patent Application No. 10-2024-0129246, filed on Sep. 24, 2024, and No. 10-2025-0125411, filed on Sep. 4, 2025, the entire contents of which are hereby incorporated by reference.

### BACKGROUND

The present disclosure herein relates to a seamless display device and a manufacturing method of the same, and more particularly, to a manufacturing method of a seamless display device including a control technology of laser lift-off.

In general, the size of a display device has continuously increased for the last decades. However, large screen uniformity is decreasing in the OLED deposition process of a large display device. Recently, a modular display technology by which appropriately-sized multiple unit modules are joined to form one large display has attracted attention. Here, it is not preferable that a display screen is disconnected at the boundary between modules when the unit modules are joined. Therefore, a display array exists on the front surface of the unit module, and circuits for driving the array typically exist on the bottom surface of the module. As a consequence, a line unit requires to be formed on a side surface of the unit module in order to connect the front surface array and the bottom surface driving unit of the module. To this end, a side wiring technology is adopted, but a production yield is significantly lowered due to failure of metal deposition and defective patterning.

### SUMMARY

The present disclosure provides a display device capable of increasing a production yield, and a manufacturing method of the same.

An embodiment of the inventive concept provides a display device manufacturing method including: providing a light shield pattern on a support substrate of a display region adjacent to a peripheral region; providing a flexible layer on the light shield pattern and the support substrate; providing a display element and a driver on the flexible layer of the display region and the peripheral region, respectively; providing laser light to the support substrate and the flexible layer of the peripheral region to separate a portion of the flexible layer from the support substrate; removing a portion of the support substrate of the peripheral region; and bending a portion of the flexible layer of the peripheral region to provide the driver on a bottom surface of the support substrate.

In an embodiment, the light shield pattern may include an opaque metal.

In an embodiment, the light shield pattern may have an L shape or a quadrangle shape.

In an embodiment, the light shield pattern may have a short-dashed line shape.

In an embodiment, the flexible layer may include polyimide or plastics

In an embodiment, the peripheral region may include: a driving region provided with the driver; and a line region provided between the driving region and the display region and having lines provided in the line region.

In an embodiment, the display device manufacturing method may further include providing a lower elastic layer provided on the flexible layer of the line region and in contact with the light shield pattern.

In an embodiment, the display device manufacturing method may further include providing an upper elastic layer on the lines and a portion of the display element.

In an embodiment, the upper elastic layer may be aligned with the light shield pattern and the lower elastic layer.

In an embodiment, the lower elastic layer and the upper elastic layer may be harder than the flexible layer.

In an embodiment of the inventive concept, a display device manufacturing method includes: providing a light shield pattern on a support substrate of a display region adjacent to a line region; providing a lower elastic layer on the support substrate of the line region; providing a display element, lines, and a driver on the flexible layer of the display region, the line region and a driving region outside the line region, respectively; providing laser light to the support substrate and the flexible layer of the line region and the driving region to separate a portion of the flexible layer from the support substrate; removing a portion of the support substrate of the line region and the driving region; and bending the flexible layer of the line region and the driving region to provide the lines and the driver to a side surface and a bottom surface of the support substrate, respectively.

In an embodiment, the lower elastic layer may include PDMS, natural rubber, synthetic rubber, or an elastic polymer.

In an embodiment, the flexible layer may include polyimide or plastics.

In an embodiment, the display device manufacturing method may further include providing an upper elastic layer on the lines and a portion of the display element.

In an embodiment, the support substrate may include a transparent glass substrate.

In an embodiment of the inventive concept, a display device includes: a support substrate; a light shield pattern provided on an edge of a top surface of the support substrate; a flexible layer provided on the light shield pattern and the top surface of the support substrate, and including a deformable layer provided on a side surface and a bottom surface of the support substrate; a display element provided on the flexible layer on the top surface of the support substrate; lines provided on the deformable layer of the side surface of the support substrate and connected to the display device; and the driver provided on the deformable layer of the bottom surface of the support substrate and connected to the lines.

In an embodiment, the display device manufacturing method may further include a lower elastic layer provided between a side wall of the support substrate and the deformable layer and in contact with the light shield pattern.

In an embodiment, the display device manufacturing method may further include an upper elastic layer provided on the deformable layer of the side surface of the support substrate and wider than the lower elastic layer.

In an embodiment, the lower elastic layer and the upper elastic layer may be harder than the flexible layer.

In an embodiment, the flexible layer may include polyimide or plastics, and the lower elastic layer and the upper elastic layer may include PDMS, natural rubber, synthetic rubber, or an elastic polymer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1 to 6 are perspective views showing example manufacturing methods of a display device according to the inventive concept;

FIGS. 7 to 12 are process cross-sectional views cut along line I-I′ of FIGS. 1 to 6;

FIG. 13 is a cross-sectional view showing an example typical display device;

FIG. 14 is a cross-sectional view showing an example typical display device;

FIGS. 15 and 16 are plan views showing example display devices according to the inventive concept;

FIG. 17 is a plan view showing an example display device according to the present inventive concept; and

FIGS. 18 to 24 are process cross-sectional views cut along line II-II′ of FIG. 17.

### DETAILED DESCRIPTION

Hereinafter, example embodiments of the present disclosure will be described in conjunction with the accompanying drawings. The above and other aspects, features, and advantages of the present disclosure will become apparent from the detailed description of the following embodiments in conjunction with the accompanying drawings. However, it should be understood that the present disclosure is not limited to the following embodiments and may be embodied in different ways. Rather, the embodiments are provided so that this disclosure will be thorough and complete and will fully convey the concept of the present disclosure to those skilled in the art, and the present disclosure will only be defined by the appended claims. Throughout this specification, like numerals refer to like elements.

The terminology used herein is for the purpose of describing embodiments and is not intended to limit the scope of the present disclosure. As used herein, the singular forms “a”, “an” and “the” are intended to include the plural forms as well, unless the context clearly indicates otherwise. It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof. Also, as just preferred embodiments, reference numerals shown according to an order of description are not limited to the order.

Moreover, example embodiments will be described herein with reference to cross-sectional views and/or plane views that are idealized example illustrations. In the drawings, the thickness of layers and regions are exaggerated for effective description of the technical details. Accordingly, variations from the shapes of the illustrations as a result, for example, of manufacturing techniques and/or tolerances, are to be expected. Thus, example embodiments should not be construed as limited to specific shapes illustrated herein but are to include deviations in shapes that result from manufacturing.

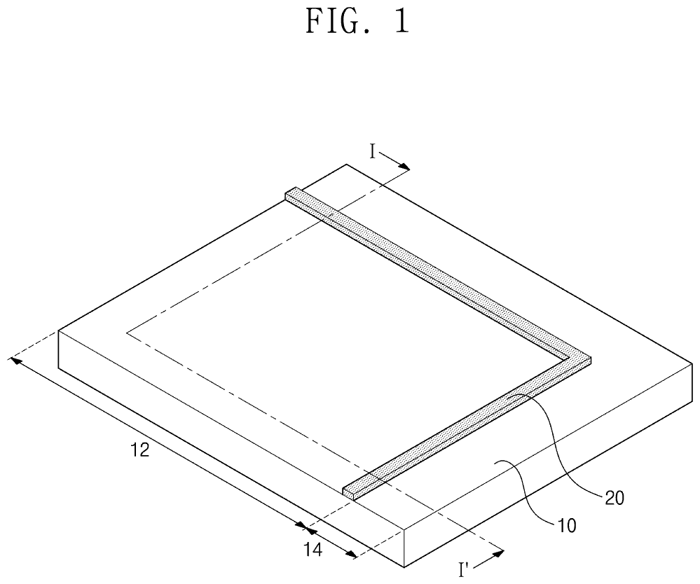

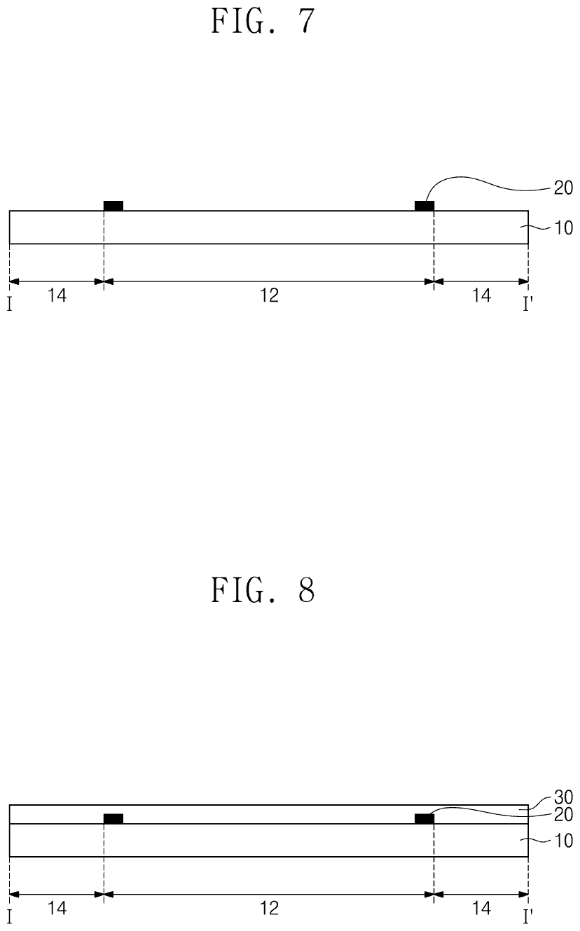

FIGS. 1 to 6 are perspective views showing example manufacturing methods of a display device according to the inventive concept. FIGS. 7 to 12 are process cross-sectional views cut along line I-I′ of FIGS. 1 to 6.

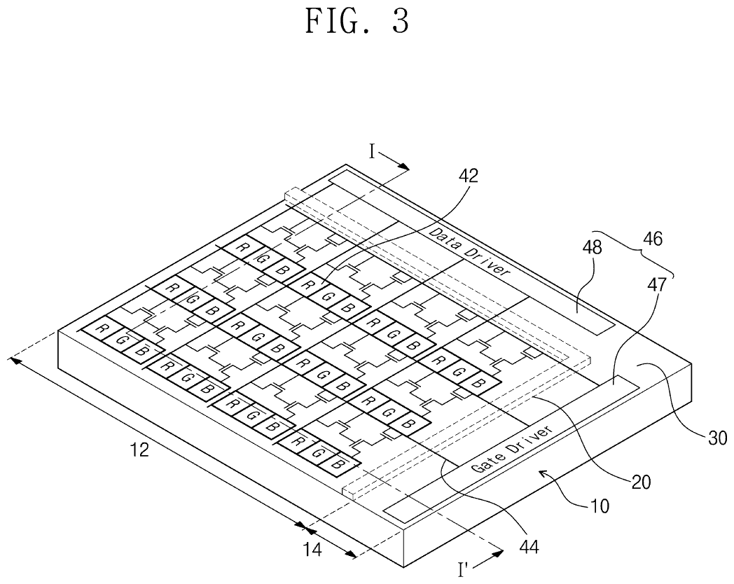

Referring to FIGS. 1 and 7, a light shield pattern 20 is provided on a support substrate 10. For example, the support substrate 10 may include a transparent glass substrate. The support substrate 10 may include a display region 12 and a peripheral region 14. The display region 12 may be a region in which a display element 42 (of FIG. 3) is provided. The peripheral region 14 may be provided in one side edge of the display region 12. The peripheral region 14 may be a region in which a driver 46 (of FIG. 3) and lines 44 (of FIG. 3) between the driver 46 and the display element 42 are provided.

The light shield pattern 20 may be provided on the support substrate 10 of the display region 12 in contact with the peripheral region 14. The light shield pattern 20 may include a light blocking pattern. The light shield pattern 20 may have an L shape in a plan view. The light shield pattern 20 may have an opaque metal pattern. For example, the light shield pattern 20 may include a black metal of chromium (Cr) or a reflective metal of aluminum (Al). Alternatively, the light shield pattern 20 may include aluminum oxide (Al₂O₃) of ceramic, and the inventive concept is not limited thereto.

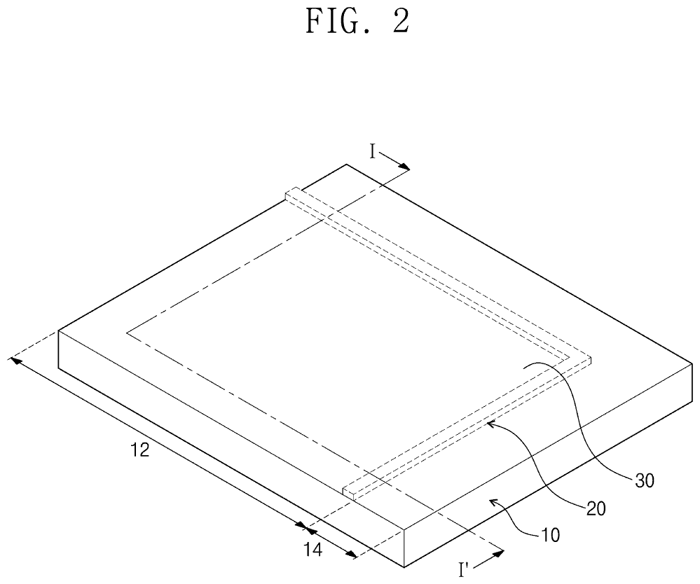

Referring to FIGS. 2 and 8, a flexible layer 30 is provided on the light shield pattern 20 and the support substrate 10. The flexible layer 30 may include a polymer layer provided in a spin coating or deposition process. For example, the flexible layer 30 may include polyimide or plastics. Additionally, the flexible layer 30 may include a thermoplastic resin or a photosensitive resin.

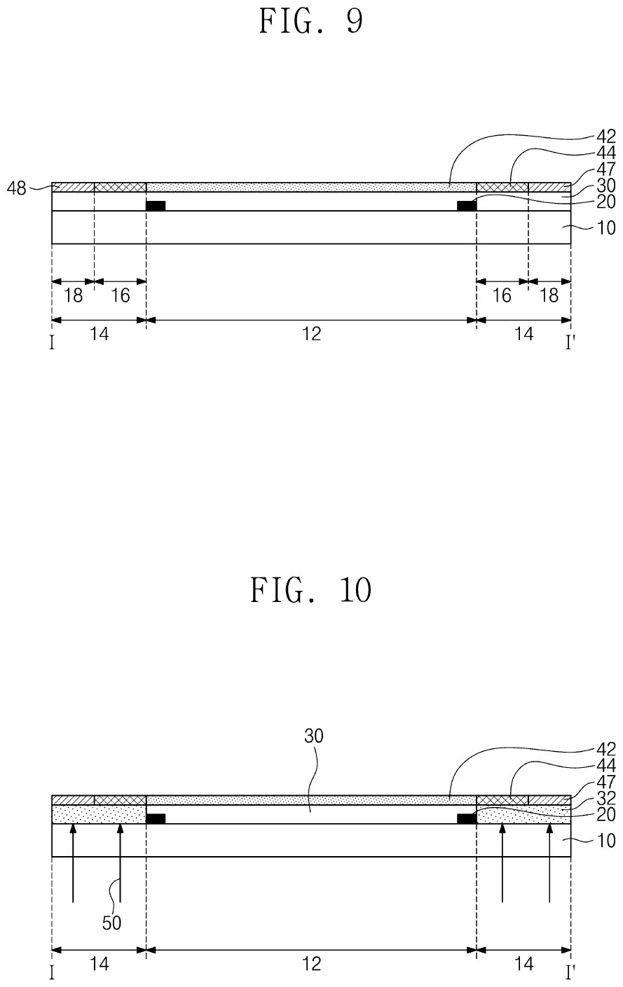

Referring to FIGS. 3 and 9, the display element 42, the lines 44, and the driver 46 are provided on the flexible layer 30. The display element 42, the lines 44, and the driver 46 may be respectively provided on the display region 12, a line region 16, and a driving region 18 on the display layer 30. The display element 42 may include light-emitting diodes of red (R), green (G), and blue (B). In addition, the display element 42 may include at least one thin-film transistor. The thin-film transistor may control a data signal provided to the light-emitting diode. The lines 44 may connect the display element 42 to the driver 46. Although not illustrated, the lines 44 may include gate lines and data lines. The gate lines and the data lines may cross each other. The gate line and the data line may be connected to the thin-film transistor of the display element 42. The driver 46 may drive the thin-film transistor of the display element 42. The driving element 46 may include a gate driver 47 and a data driver 48. The gate driver 47 may be provided in the driving region 18 at one side of the display region 12. The gate driver 47 may be connected to the gate line and provide a gate signal or a scan signal to the thin-film transistor. The data driver 48 may be provided in the driving region 18 at another side of the display region 12. The data driver 48 may be connected to the data line and provide the data signal to the thin-film transistor and the display element 42. The display element 42 may display the colors of red (R), green (G), and blue (B) in response to the data signal.

Although not illustrated, a protection film may be provided on the display element 42, the lines 44, and the driver 46. For example, the protection film may include a transparent plastic layer.

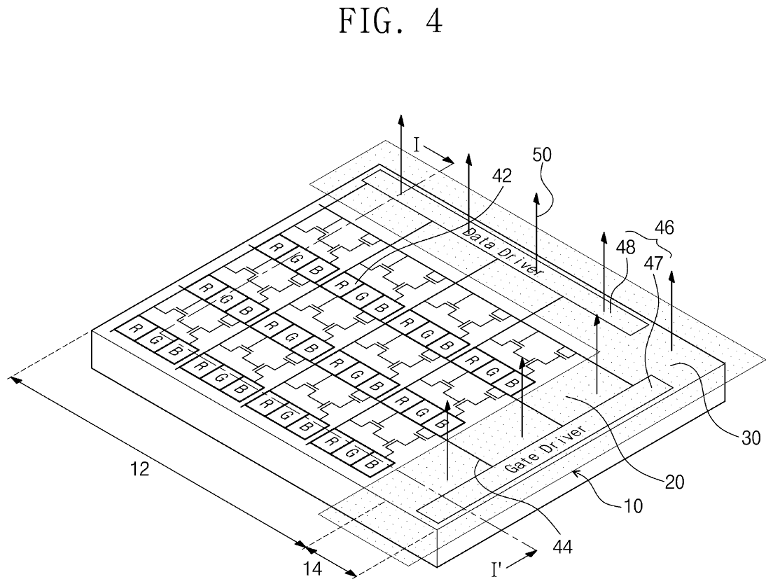

Referring to FIGS. 4 and 10, the laser light 50 is provided to the peripheral region 14 of the support substrate 10 to separate a portion of the flexible layer 30 from the support substrate 10. The laser light 50 may transmit through the support substrate 10 to be provided to the flexible layer 30. The flexible layer 30 of the peripheral region 14 may be melted by the laser light 50 to be separated from the support substrate 10. In contrast, the flexible layer 30 may be sensitive to the laser light 50 to lose the adhesive force. The flexible layer 30 separated from the support substrate 10 may be defined as a deformable layer 32.

According to an example, the light shield pattern 20 may define an exposure region of the laser light 50 corresponding to the peripheral region 14. The light shield pattern 20 may be provided in the display region 12 adjacent to the peripheral region 14 to absorb or reflect the laser light 50, and thus prevent reduction in the adhesive force of the support substrate 10 and the flexible layer 30 of an edge of the display region 12. Alternatively, the light shield pattern 20 may bond the support substrate 10 and the flexible layer 30 of the edge of the display region 12, and the inventive concept is not limited thereto.

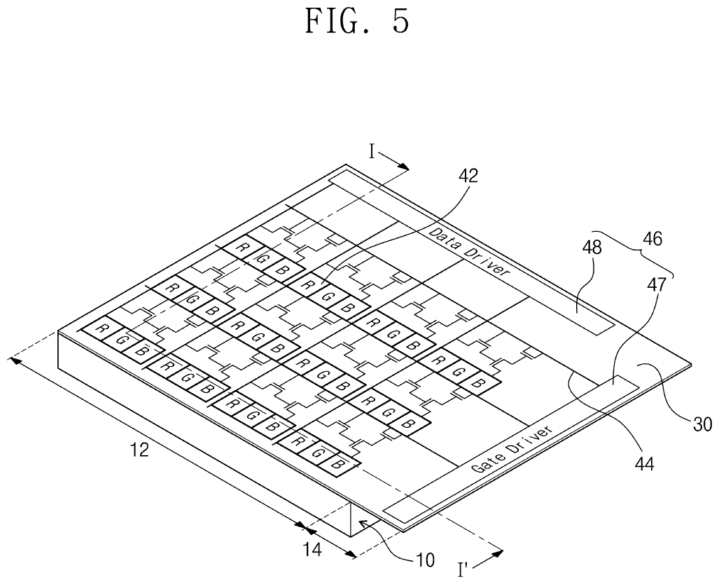

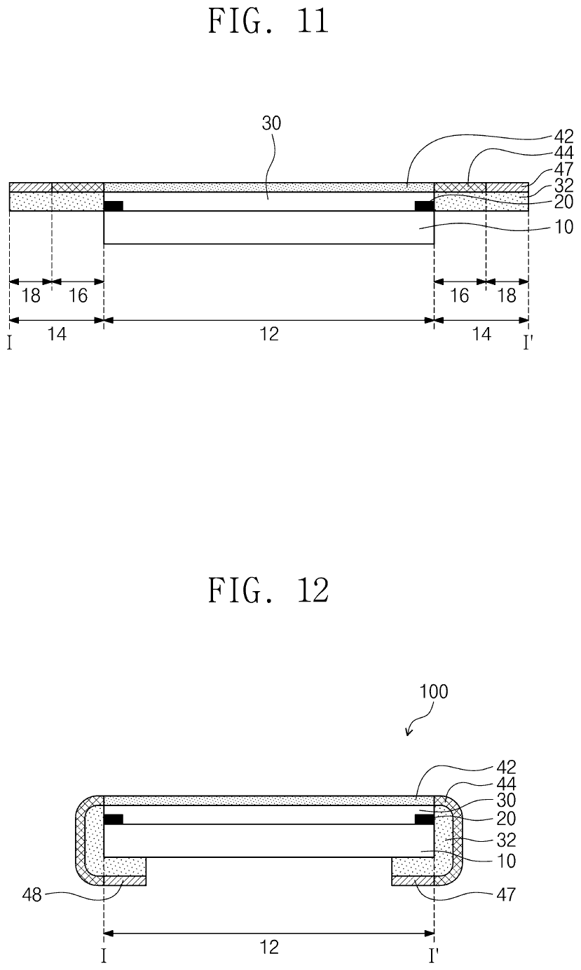

Referring to FIGS. 5 and 11, a portion of the support substrate 10 of the peripheral region 14 is removed. The support substrate 10 of the peripheral region 14 may be removed in a scribing process. The support substrate 10 under the deformable layer 32 may be removed. The exposure process and scribing process of the laser light 50 may be called as a laser lift-off process. The support substrate 10 of the display region 12 may support the flexible layer 30. The planar region of the support substrate 10 may be reduced.

Although not illustrated, corner portions of the deformable layer 32 between the gate driver 47 and the data driver 48 are removed. The corner portions of the deformable layer 32 may be removed in a cutting process or sawing process.

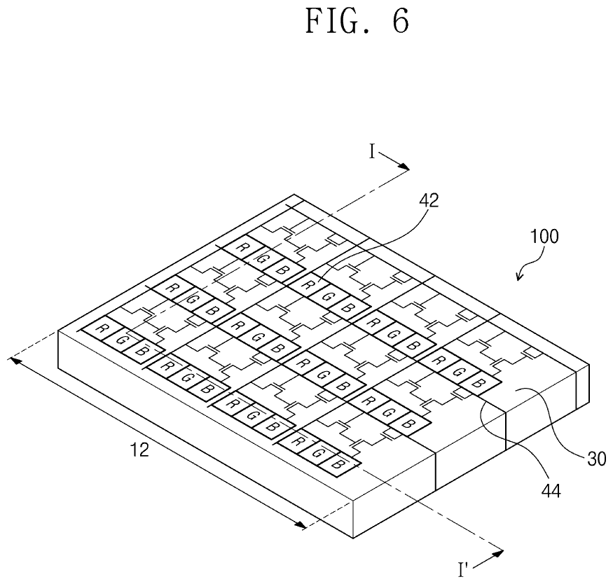

Referring to FIGS. 6 and 12, a portion of the flexible layer 30 of the peripheral region 14 is bent, and the gate driver 47 and the data driver 48 are provided on the bottom surface of the support substrate 10. The display element 42 may be provided on the top surface of the support substrate 10. The deformable layer 32 of the line region 16 and the driving region 18 may be provided, without pores, on a side wall and the bottom surface of the support substrate 10 of the display region 12. The deformable layer 32 of the line region 16 may contact or be adhered to a side surface of the support substrate 10. The lines 44 may be provided on the deformable layer 32 of the side surface of the support substrate 10 and may connect the display element 42 to the driver 46. The deformable layer 32 of the driving region 18 may contact or be adhered to the bottom surface of the support substrate 10. The driver 46 may be provided on the deformable layer 32 of the bottom surface of the support substrate 10. The protection film (not shown) on the display element 42, the lines 44, and the driver 46 may be removed. Accordingly, the display device 100 according to an embodiment of the inventive concept may be manufactured as a seamless display panel module.

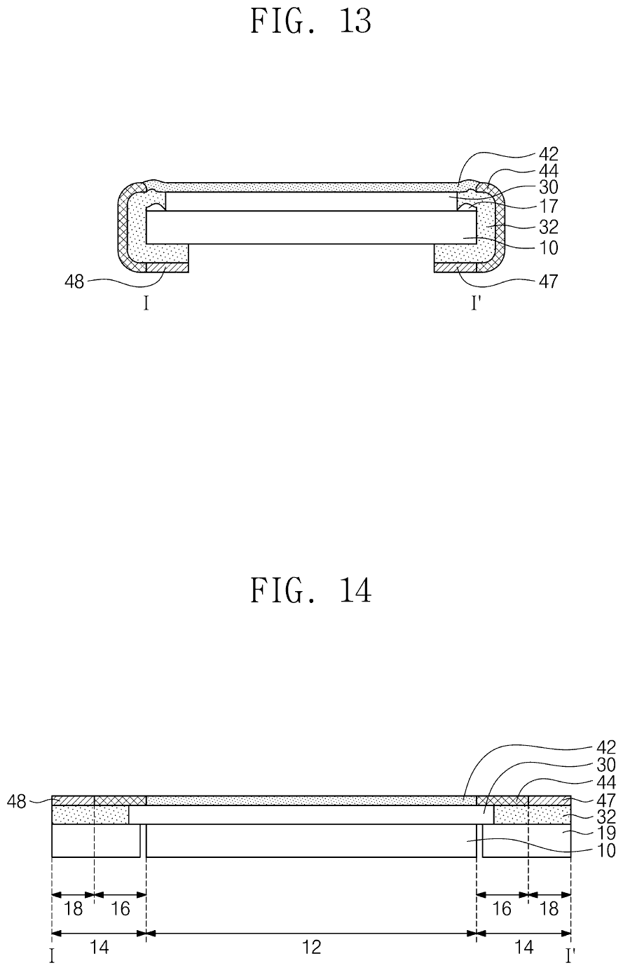

FIG. 13 shows an example typical display device.

Referring to FIG. 13, the typical display device 200 may have lift defects 17. The lift defects 17 may be derived by wide exposure of the laser light 50 to the flexible layer 30. When the laser light 50 is provided to the flexible layer 30 of the display region 12, the flexible layer 30 of the display region 12 may be partially separated from the support substrate 10 to have the lift defects 17.

FIG. 14 shows an example typical display device 200.

Referring to FIG. 14, the typical display device 200 may have substrate separation defects 19 of the support substrate 10. The substrate separation defects 19 may be derived by narrow exposure of the laser light 50 to the flexible layer 30. When the laser light 50 is narrowly provided to the flexible layer 30 of the peripheral region 14, the support substrate 10 of the peripheral region 14 may be adhered to the flexible layer 30 of the peripheral region 14 after the scribing process or the sawing process, and derive the substrate separation defects 19.

Referring to FIGS. 10 to 12 again, the light shield pattern 20 may define an exposure region of the laser light 50 to reduce or minimize over-exposure or narrow exposure of the laser light 50. Namely, the light shield pattern 20 may prevent the lift defects 17 and the substrate separation defects 19 of the flexible layer 30.

Accordingly, a manufacturing method of the display device 100 according to an embodiment of the inventive concept may increase a production yield using the light shield pattern 20 that defines an exposure region of the laser light 50 to prevent the lift defects 17 and the substrate separation defects 19 of the flexible layer 30.

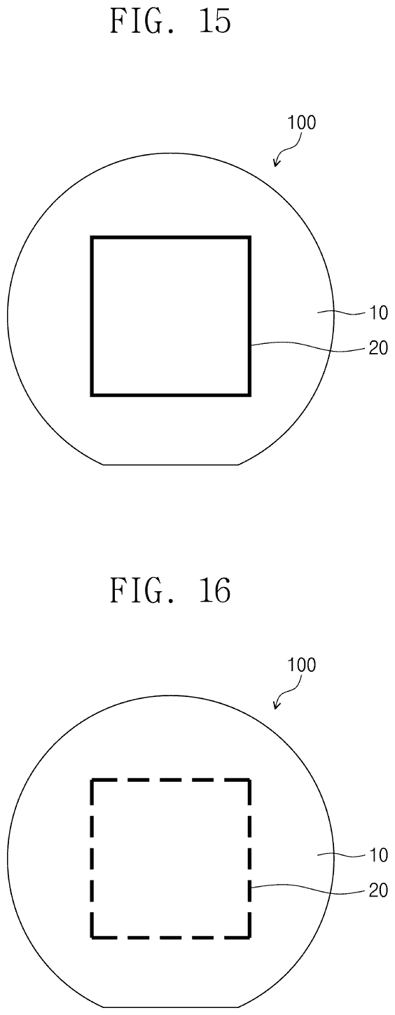

FIGS. 15 and 16 show example display devices 100 according to the inventive concept.

Referring to FIG. 15, the light shield pattern 20 of the display device 100 of the inventive concept may have a quadrangle shape in a plan view. Although not illustrated, the light shield pattern 20 may have an I or U shape as well as the quadrangle shape. In addition, the I or U shape may be provided on one side, both sides, or four sides of the support substrate 10.

Referring to FIG. 16, the light shield pattern 20 of the display device 100 of the inventive concept may have a short-dashed line shape.

FIG. 17 shows an example display device 100 according to the inventive concept.

Referring to FIG. 17, the display device 100 according to an embodiment of the inventive concept may include a lower elastic layer 60 and an upper elastic layer 70. The lower elastic layer 60 may be provided in the line region 16. The upper elastic layer 70 may be provided in the line region 16 and a portion of the display region 12. The upper elastic layer 70 may be wider than the lower elastic layer 60. The upper elastic layer 70 may have the same width as those of the lower elastic layer 60 and the light shield pattern 20. The lower elastic layer 60 and the upper elastic layer 70 may protect the deformable layer 32 (of FIG. 24) when the deformable layer is bent.

The light shield pattern 20, the display element 42, the lines 44, and the driver 46 may be configured same as those of FIGS. 1 to 6.

The manufacturing method of the display device 100 configured in this way according to the inventive concept will be described as the following.

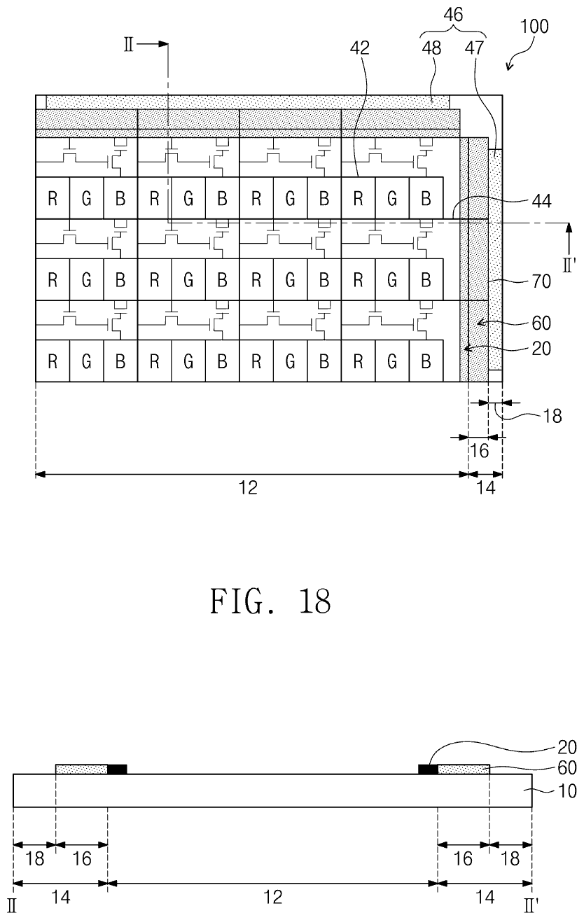

FIGS. 18 to 24 are process cross-sectional views cut along line II-II′ of FIG. 17.

Referring to FIGS. 1 and 7, the light shield pattern 20 is provided in an edge of the display region 12 adjacent to the peripheral region 14 of the support substrate 10.

Referring to FIG. 18, the lower elastic layer 60 is provided on the support substrate 10 of the line region 16. The lower elastic layer 60 may contact one side of the light shield pattern 20. According to an example, the lower elastic layer 60 may have higher hardness than the flexible layer 30 (of FIG. 19). The lower elastic layer 60 may be harder than the flexible layer 30. The lower elastic layer 60 may prevent high step defects of the light shield pattern 20. For example, the lower elastic layer 60 may include PDMS, natural rubber, synthetic rubber, or an elastic polymer. Although not illustrated, a thermoplastic adhesive or a photosensitive thermoplastic adhesive may be provided between the lower elastic layer 60 and the support substrate 10.

Referring to FIG. 19, the flexible layer 3 is provided on the support substrate 10, the light shield pattern 20, and the lower elastic layer 60. The flexible layer 30 may be softer or more flexible than the lower elastic layer 60. For example, the flexible layer 30 may include polyimide or plastics.

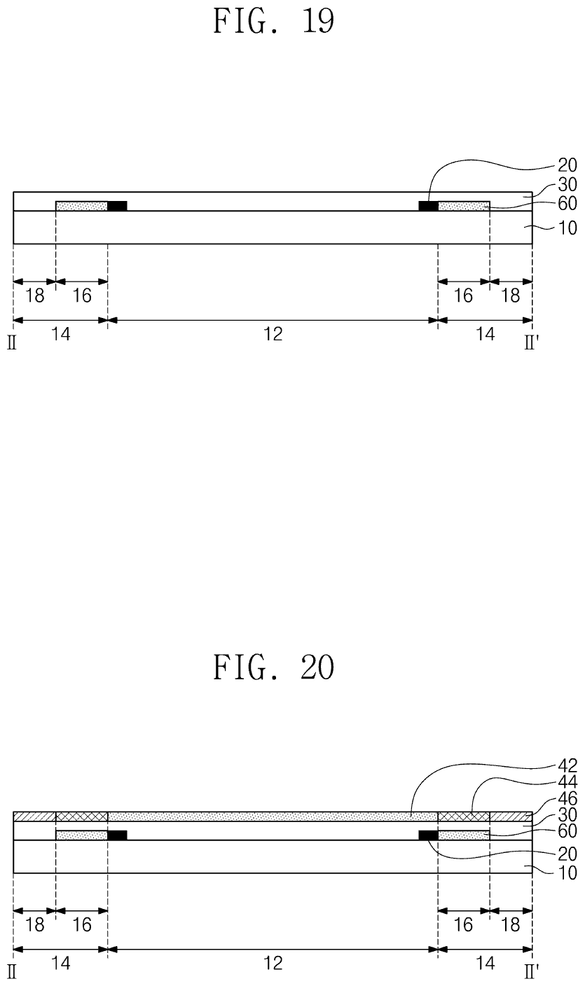

Referring to FIG. 20, the display element 42, the lines 44, and the driver 46 are respectively provided on the display region 12, the line region 16, and the driving region 18 of the flexible layer 30. The display element 42, the lines 44, and the driver 46 may be configured same as those of FIG. 9.

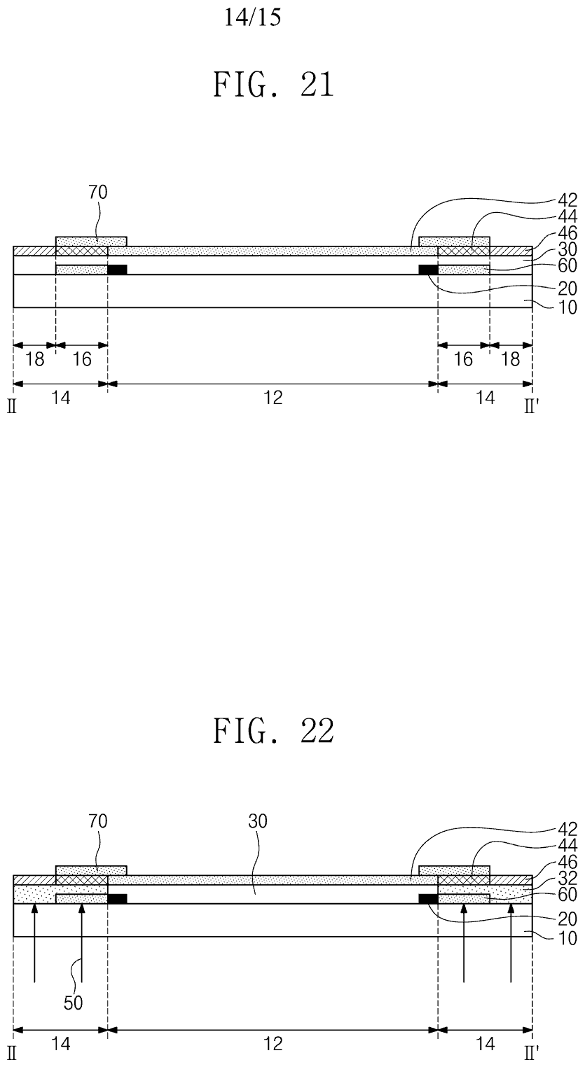

Referring to FIGS. 17 and 21, the upper elastic layer 70 is provided on a portion of the lines 44 and the display element 42. The upper elastic layer 70 may be wider than the lower elastic layer 60. The upper elastic layer 70 may have a larger width than the lower elastic layer 60. The upper elastic layer 70 may be aligned with the light shield pattern 20 and the lower elastic layer 60. One side of the upper elastic layer 70 may be aligned with one side of the lower elastic layer 60. The other side of the upper elastic layer 70 may be aligned with the one side of the lower elastic layer 60. The width of the upper elastic layer 70 may be the same as that of the light shield pattern 20 and the lower elastic layer 60. The upper elastic layer 70 may be harder than the flexible layer 30. The upper elastic layer 70 may include the same material as that of the lower elastic layer 60. For example, the upper elastic layer 70 may include PDMS, natural rubber, synthetic rubber, or an elastic polymer.

Referring to FIG. 22, the laser light 50 is provided to the peripheral region 14 of the support substrate 10 to partially separate the flexible layer 30 from the support substrate 10. The laser light 50 may transmit through the support substrate 10 to be provided to the lower elastic layer 60 and the flexible layer 30. The lower elastic layer 60 and the flexible layer 30 of the peripheral region 14 may be separated from the support substrate 10. The flexible layer 30 of the peripheral region 14 may be the deformable layer 32, and be melted by the laser light 50 or lose the adhesive force due to the laser light 50 to be separated from the support substrate 10. When the thermoplastic adhesive or photosensitive thermoplastic adhesive between the lower elastic layer 60 and the support substrate 10 is heated by the laser light 50, the lower elastic layer 60 and the support substrate 10 may be separated from each other.

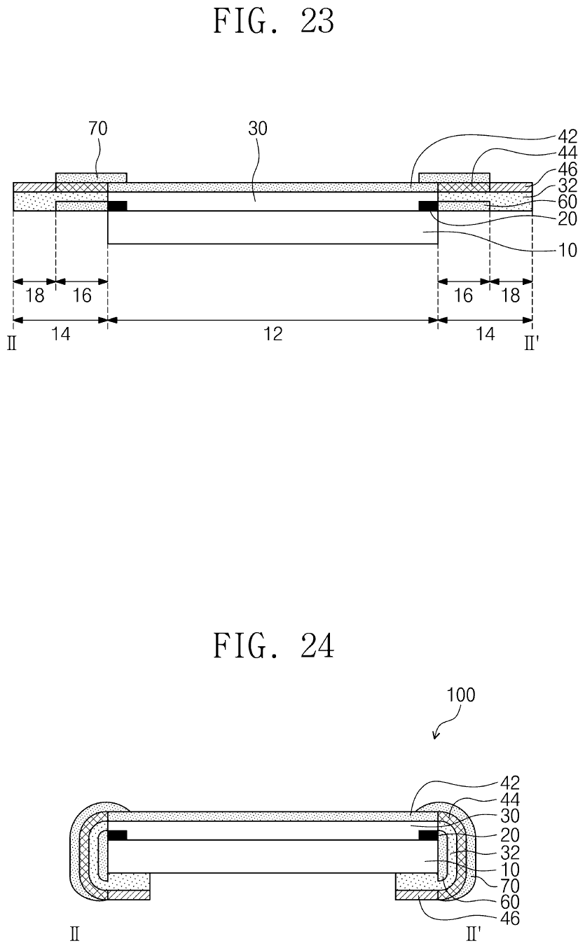

Referring to FIG. 23, a portion of the support substrate 10 of the peripheral region 14 is removed. The support substrate 10 may be removed from the peripheral region 14 in the scribing process.

Although not illustrated, corner portions of the deformable layer 32 between the gate driver 47 and the data driver 48 are removed. The corner portions of the deformable layer 32 may be removed in a cutting process or a sawing process.

Referring to FIG. 24, a portion of the flexible layer 30 of the peripheral region 14 is bent, and the gate driver 47 and the data driver 48 are provided to the bottom surface of the support substrate 10. The deformable layer 32 may be provided, without pores, to a side wall and the bottom surface of the support substrate 10 of the display region. The lower elastic layer 60 may prevent high step defects when the deformable layer 32, which gets thin due to the light shield pattern 20, is bent. In addition, the upper elastic layer 70 may prevent stretchable defects of the deformable layer 32.

Eventually, the manufacturing method of the display device 100 according to an embodiment of the inventive concept may prevent the lift detects 17, the substrate separation defects 19, the high step defects, or the stretchable defects to increase a production yield using the light shield pattern 20 defining the exposure region of the laser light 50, the lower elastic layer 60, and the upper elastic layer 70.

As described above, the seamless display device manufacturing method according to an embodiment of the inventive concept may increase a production yield by preventing lift defects and substrate separation defects of the flexible layer by means of the light shield pattern that is provided at an edge of the display region in contact with the peripheral region to define the exposure region of the laser light.

Although the embodiments of the inventive concept have been described with reference to the accompanying drawings, those ordinary skilled in the art can readily understand that the inventive concept may be implemented in other specific forms without changing the technical spirit or essential features of the inventive concept. It is therefore to be understood that the above-described embodiments are illustrative in all aspects and not restrictive.

What is claimed is:

1. A display device manufacturing method comprising:
providing a light shield pattern on a support substrate of a display region adjacent to a peripheral region;
providing a flexible layer on the light shield pattern and the support substrate;
providing a display element and a driver on the flexible layer of the display region and the peripheral region, respectively;
providing laser light to the support substrate and the flexible layer of the peripheral region to separate a portion of the flexible layer from the support substrate;
removing a portion of the support substrate of the peripheral region; and
bending a portion of the flexible layer of the peripheral region to provide the driver on a bottom surface of the support substrate.

2. The display device manufacturing method of claim 1, wherein the light shield pattern comprises an opaque metal.

3. The display device manufacturing method of claim 1, wherein the light shield pattern has an L shape or a quadrangle shape.

4. The display device manufacturing method of claim 1, wherein the light shield pattern has a short-dashed line shape.

5. The display device manufacturing method of claim 1, wherein the flexible layer comprises polyimide or plastics.

6. The display device manufacturing method of claim 1, wherein
the peripheral region comprises:
a driving region provided with the driver; and
a line region provided between the driving region and the display region and having lines provided in the line region.

7. The display device manufacturing method of claim 6, further comprising:
providing a lower elastic layer provided on the flexible layer of the line region and in contact with the light shield pattern.

8. The display device manufacturing method of claim 7, further comprising:
providing an upper elastic layer on the lines and a portion of the display element.

9. The display device manufacturing method of claim 8, wherein
the upper elastic layer is aligned with the light shield pattern and the lower elastic layer.

10. The display device manufacturing method of claim 8, wherein
the lower elastic layer and the upper elastic layer are harder than the flexible layer.

11. A display device manufacturing method comprising:
providing a light shield pattern on a support substrate of a display region adjacent to a line region;
providing a lower elastic layer on the support substrate of the line region;
providing a display element, lines, and a driver on the flexible layer of the display region, the line region and a driving region outside the line region, respectively;
providing laser light to the support substrate and the flexible layer of the line region and the driving region to separate a portion of the flexible layer from the support substrate;
removing a portion of the support substrate of the line region and the driving region; and
bending the flexible layer of the line region and the driving region to provide the lines and the driver to a side surface and a bottom surface of the support substrate, respectively.

12. The display device manufacturing method of claim 11, wherein
the lower elastic layer comprises PDMS, natural rubber, synthetic rubber, or an elastic polymer.

13. The display device manufacturing method of claim 11, wherein the flexible layer comprises polyimide or plastics.

14. The display device manufacturing method of claim 11, further comprising:
providing an upper elastic layer on the lines and a portion of the display element.

15. The display device manufacturing method of claim 1, wherein the support substrate comprises a transparent glass substrate.

16. A display device comprising:
a support substrate;
a light shield pattern provided on an edge of a top surface of the support substrate;
a flexible layer provided on the light shield pattern and the top surface of the support substrate, and comprising a deformable layer provided on a side surface and a bottom surface of the support substrate;
a display element provided on the flexible layer on the top surface of the support substrate;
lines provided on the deformable layer of the side surface of the support substrate and connected to the display device; and
the driver provided on the deformable layer of the bottom surface of the support substrate and connected to the lines.

17. The display device manufacturing method of claim 16, further comprising:
a lower elastic layer provided between a side wall of the support substrate and the deformable layer and in contact with the light shield pattern.

18. The display device manufacturing method of claim 17, further comprising:
an upper elastic layer provided on the deformable layer of the side surface of the support substrate and wider than the lower elastic layer.

19. The display device manufacturing method of claim 18, wherein
the lower elastic layer and the upper elastic layer are harder than the flexible layer.

20. The display device manufacturing method of claim 18, wherein
the flexible layer comprises polyimide or plastics, and
the lower elastic layer and the upper elastic layer comprise PDMS, natural rubber, synthetic rubber, or an elastic polymer.
